(19) United States
(12) Patent Application Publication
(10) Pub. No.: US 2003/0096502 A1
(43) Pub. Date: May 22, 2003

(54) Method for levelling depressed surface of organic crystals

(76) Inventors: Hiroshi Nanjo, Miyagi-gun (JP); Kyoji Komatsu, Sendai-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/285,474

(22) Filed: Nov. 1, 2002

(30) Foreign Application Priority Data
Nov. 16, 2001 (JP) 2001-351172

(51) Int. Cl. H01L 21/302; H01L 21/461

(52) U.S. Cl. 438/689

(57) ABSTRACT

The invention discloses a method for imparting molecular-level smoothness to the surface of an organic crystal used as a non-linear optical material having a defective depression by levelling the surface depression so as to be free from a decrease in the incidence of a laser beam and energy transducing efficiency. The method comprises: bringing into contact a microprobe having a specified radius of curvature at the probe tip onto the crystal surface with a defective depression under a specified contacting load; scanning the surface with the probe to shave off the surface around the depression forming shavings; and transferring the shavings into the depression to fill the depression up to a flatness level flush with the level around the filled depression.

### BACKGROUND OF THE INVENTION

The present invention relates to a method for levelling a surface of an organic crystal having a depression. More particularly, the invention relates to a method for flattening or levelling the surface of an organic crystal used as a non-linear optical material having a depression as a defect such as scratches and pits so as to provide an organic crystal free from a loss in the laser beam incidence and energy transducing efficiency.

It is a well established technology to utilize certain crystalline materials as a non-linear optical material. It is essential in this technology to ensure perfect flatness or smoothness of the crystal surface in a molecular level flatness in order to minimize the loss in the laser beam incidence and energy transducing efficiency inherent in the crystalline material per se. As compared with inorganic crystals, organic crystals in general have a fairly low surface hardness and are sometimes liable to the occurrence of surface defects such as scratches and pits resulting in a loss of the optical properties inherent in the crystalline material.

It is therefore desirable for such an organic crystal having a depressive surface defect that the depression is efficiently levelled to recover molecular-level smoothness of the crystal surface. Since the organic crystals used as a non-linear optical material are usually single crystals, it is necessary to fill the defective surface depression with a filling material of the same kind as the single crystal body so as to minimize the loss in the requisite properties such as laser beam incidence and energy transducing efficiency at the interface between the filling of the depression and the base body of the single crystal.

Several methods are proposed in the prior art for levelling a defective depressed surface of a relatively soft and weak non-linear optical material such as certain organic crystals including a method of mechanical polishing of the whole surface as disclosed in Japanese Patent Kokai 5-309560 and a method of subjecting the surface to finishing by utilizing a mechanochemical reaction disclosed in Japanese Patent Kokai 5-285827. Since the surface polishing work in each of these methods is conducted over the whole surface including the defective depression to accomplish full levelling of the surface, these methods are not suitable for local levelling of a limited scratch or pit. In the former method above, in particular, the depth of a depression which can be levelled by the method is limited to about 1 μm at the smallest and the optical properties inherent in the material can not always be fully maintained at the interface.

Japanese Patent Kokai 4-1951 proposes application of the Langmuir-Blodgett method (referred to as the LB method hereinafter) to the preparation of an organic thin film having a smooth surface with roughness of 1 nm or smaller. This method, however, is not suitable for levelling of molecular-order scratches or depressions such as molecular defects.

The inventors previously proposed (Japanese Patent Kokai 2001-105285) a method for obtaining an organic ionic crystal having a flat surface in which a probe is brought into contact with the crystal surface under a contacting load and the whole surface of the crystal is shaved by two-dimensionally scanning the surface with the probe. This method is also not suitable when local levelling is desired for a defective depression occurring in the surface.

Thus, it is the present status of the art that no efficient method is known for local levelling of a scratch or a pit subsequently produced on the surface of an organic crystal once levelled in a molecular level or obtained by whole-surface polishing.

### SUMMARY OF THE INVENTION

In view of the above described problems and disadvantages in the prior art, the present invention has an object to provide a method for obtaining an organic crystal for use as a non-linear optical material having a fully smoothened surface so as to be free from a decrease in the laser beam incidence or energy transducing efficiency by locally levelling a scratch or pit as a defective depression in a novel method capable of accomplishing an ultimate smooth surface with molecular scale flatness.

Thus, the present invention provides a method for the preparation of an organic crystal having a fully smoothened surface which comprises the steps of:

(a) bringing a probe at a probe tip thereof having a radius of curvature in the range from 1 nm to 100 nm into contact with the surface of an organic crystal having a depression under a contacting load in the range from 1 nN to 100 nN;

(b) two-dimensionally scanning the surface with the probe under the contacting load to shave off the circumferential portions of the crystal around the depression forming shavings; and

(c) transferring the shavings into the depression to fill the depression therewith up to a level flush with the surface level around the depression.

The thus treated surface of the crystal is extremely flat since the surface roughness is far below the molecular step height which is 0.89 nm.

### BRIEF DESCRIPTION OF THE DRAWING

FIGS. 1A, 1B, 1C and 1D are each a microscopic photograph of the surface of an organic crystal in the course of a levelling treatment of surface depressions carried out in Example 1.

FIGS. 2A, 2B and 2C are each a microscopic photograph of the surface of an organic crystal in the course of a levelling treatment of a depression carried out in Example 2.

### DETAILED DESCRIPTION OF THE PREFERRED EMBODIMENTS

The method of the present invention for local levelling of a defective depression in the surface of an organic crystal used as a non-linear optical material is applicable to single crystals of a variety of organic compounds without particular limitations but the method would be most successful when the crystal is of an organic compound selected from the group consisting of 4-dimethylaminostilbazolium salts, L-arginine phosphates, 4-nitroaniline, 2-methyl-4-nitroaniline, 2-methyl-4-nitro-N-methylaniline, 3-acetamido-4-dimethylamino nitro-benzene, N-(5-nitro-2-pyridyl)-5-prolinol, N,N-dimethylamino-nitrostilbene and the like.

These organic crystals are generally soft and weak as compared with most inorganic crystals so that, even if the crystal be once imparted with a fully smoothened surface, the surface is liable to be damaged by a thermal or mechanical shock or by receiving a chemical attack from outside forming a defective depression.

It is possible by properly undertaking the inventive method to effect full leveling of depressions having a maximum depth Rmax not exceeding 50 nm and a center line-average surface roughness Ra not exceeding 5 nm or, in particular, molecular level fine depressions having a maximum depth Rmax not exceeding 3 nm and a center line-average surface roughness Ra not exceeding 1 nm.

The objective body to which the inventive method is applicable is not limited to isolated single crystals of the above named organic compounds but the method is applicable to a coating layer formed on a variety of substrates such as metal plates, glass plates and ceramic plates by a conventional film-forming method such as vacuum vapor deposition method and chemical vapor-phase deposition (CVD) method and also to an accumulated multilayered film formed by the LB method.

The inventive method for levelling of a defective depression in the surface of an organic crystal is conducted by two-dimensionally scanning the surface on and around the depression with a probe to shave off the circumferential portions around the depression forming shavings and then transferring the shavings into the depression so as to fill the depression with the shavings up to the same level as the flat surface around the depression.

With regard to the probe used in the inventive method, it is convenient to divertedly employ a probe equipped in an atomic force microscope if the probe tip of the probe has an appropriate radius of curvature although the probe is not particularly limitative provided that the contacting load to the crystal surface can be adequately controlled within the specified range.

It is important in the inventive method that the probe tip of the probe to be contacted with the crystal surface has a radius of curvature in the range from 1 nm to 100 nm or, preferably, from 5 nm to 40 nm. The contacting load on the probe during surface scanning should be controlled in the range from 1 nN to 100 nN or, preferably, from 5 nN to 30 nN. When a probe of which the probe tip has a radius of curvature smaller than 1 nm is used, shaving of the crystal surface cannot be complete while, when the radius of curvature is too large, the surface formed by shaving cannot be imparted with molecular level smoothness. When the contacting load on the probe is too small, shaving of the surface can hardly be carried out with smoothness while, when the contacting load is too large, shaving of the surface sometimes proceeds overly not to give a fully smoothened surface as desired.

It is necessary in the inventive method that scanning of the surface with the probe is conducted as many times as necessary until the defective depression on the surface is completely filled with the shavings produced by shaving of the circumferential area around the depression and then transferred into the depression. Scanning with the probe repeated 3 to about 20 times is sufficient in most cases though dependent on various factors including size and depth of the depression to be levelled, radius of curvature of the probe tip of the probe, contacting load on the probe during scanning and others. By properly conducting the inventive method, a defective depression formed on an organic crystal disappears almost completely to give an organic crystal of which the surface has molecular-level smoothness.

In the following, the method of the present invention is described in more detail by way of Examples and a Comparative Example, which, however, never limit the scope of the invention in any way.

### Example 1

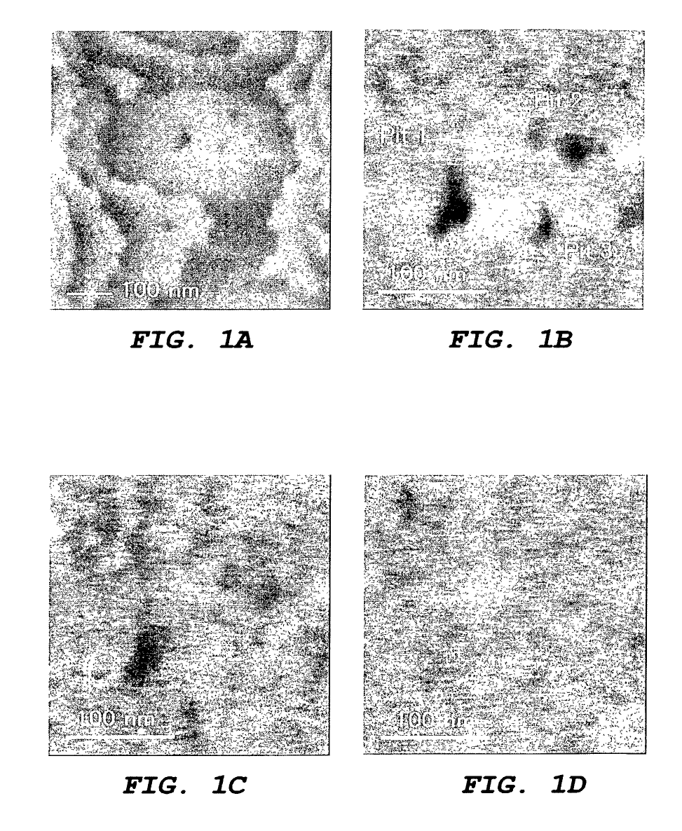

The organic crystal subjected to the surface levelling treatment according to the inventive method was a single crystal of 4-(4-dimethylaminostyryl)-1-methylpyridinium tosylate (referred to as DAST hereinafter) having a stepped structure as shown in the photograph of FIG. 1A, of which a crystallographic (001) surface of molecular-level flatness had three pit-like defective depressions as indicated in the photograph of FIG. 1B including Pit 1 having a length of 72 nm and depth of 0.70 nm, Pit 2 having a length of 35 nm and depth of 0.74 nm and Pit 3 having a length of 45 nm and depth of 0.59 nm.

A 600 nm by 600 nm square area of the crystal surface including these three pits was scanned two-dimensionally with a probe of an atomic force microscope, of which the probe tip had a radius of curvature of 20 nm, by the contact method under a vertical contacting load of 14 nN to find levelling of the Pit 3 after only 3 times of scanning (see FIG. 1C) and levelling of the Pits 1 and 2 after 8 times of scanning (see FIG. 1D).

As is understood from FIG. 1A, this DAST crystal had a stepped structure of 0.9 nm corresponding to the thickness of the DAST ion pair and the flat portion thereof had a terrace-formed configuration. It was indicated therefore that the defective depressions found there could be levelled to impart molecular level smoothness to the flat terrace or, namely, a possibility was indicated for molecular-level levelling of depressions. The thus treated surface was extremely flat since the surface roughness was far below the molecular step height which was 0.89 nm.

By this levelling treatment, the center line-average surface roughness Ra of the crystal surface shown in FIG. 1B was decreased from 0.11 nm to 0.05 nm.

### Example 2

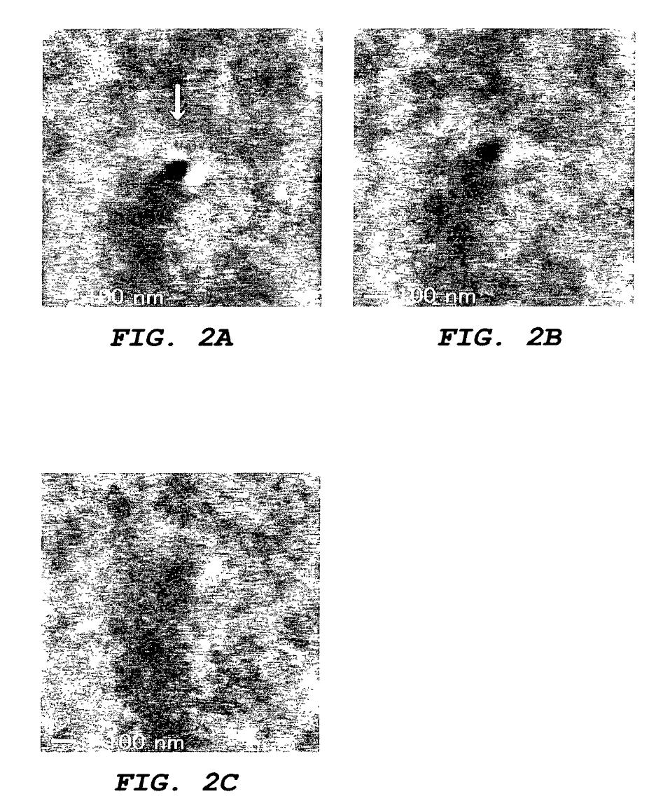

The crystallographic (001) surface of a DAST single crystal with a roughness Rmax of 5.4 nm to be subjected to the levelling treatment had a pit-like defective depression of 109 nm length and 5.4 nm depth as indicated by the arrow in FIG. 2A. The procedure for the levelling treatment was substantially the same as in Example 1 except that the vertical contacting load on the probe was 19 nN instead of 14 nN and scanning was conducted on a 1110 nm by 1110 nm square area including the pit. By repeating the two-dimensional scanning with the probe, the depth of the pit was decreased to 2.5 nm after 4 times of repeated scanning (see FIG. 2B) and the pit disappeared completely after 10 times of repeated scanning (see FIG. 2C). The center line-average surface roughness Ra of 0.31 nm before the levelling treatment remained unchanged by this treatment. The thus levelling-treated area of the crystal surface had a roughness about equivalent to the surface roughness of the base surface therearound.

### Comparative Example

The same experimental procedure as in Example 2 was undertaken excepting for an increase of the contacting load on the probe from 19 nN to 130 nN. The results were that shaving of the crystal surface took place at unlimited portions of the surface including the depression so that the treated surface was coarse with undulation and had a surface roughness Ra of 50 nm.

What is claimed is:

1. A method for the preparation of an organic single crystal having a surface with molecular-level smoothness which comprises the steps of:
(a) bringing a probe at a probe tip thereof having a radius of curvature in the range from 1 nm to 100 nm into contact with a surface of the organic single crystal having a depression under a contacting load in the range from 1 nN to 100 nN;
(b) two-dimensionally scanning the surface of the organic single crystal with the probe under the contacting load around the depression forming shavings; and
(c) transferring the shavings into the depression to fill the depression therewith up to a level flush with the surface level around the depression.

2. The method according to claim 1 in which the probe tip of the probe has a radius of curvature in the range from 5 nm to 40 nm.

3. The method according to claim 1 in which the contacting load on the probe is in the range from 5 nN to 30 nN.

4. The method according to claim 1 in which the two-dimensional scanning of the surface with the probe is repeated from 3 times to 20 times.
